(19) United States
(12) Patent Application Publication
(10) Pub. No.: US 2011/0083729 A1
(43) Pub. Date: Apr. 14, 2011

(54) Multi-Junction Solar Cell

(75) Inventors: Shih-Chang Lee, Hsinchu (TW); Yi-Chieh Lin, Hsinchu (TW)

(73) Assignee: Epistar Corporation

(21) Appl. No.: 12/896,824

(22) Filed: Oct. 1, 2010

(30) Foreign Application Priority Data
Oct. 2, 2009 (TW) 098133677

(51) Int. Cl. H01L 31/06

(52) U.S. Cl. 136/255

(57) ABSTRACT

A solar cell includes a substrate; a buffer layer located on the substrate; a SiₓGe₍₁₋ₓ₎ bottom cell located on the buffer layer; a first tunneling layer located on the SiₓGe₍₁₋ₓ₎ bottom cell; a GaN_{y}As_{(1-y)} middle cell located on the first tunneling layer; a second tunneling cell located on the GaN_{y}As_{(1-y)} middle cell; a Ga_{z}In_{(1-z)}P top cell located on the second tunneling layer; and a contact layer located on the Ga_{z}In_{(1-z)}P top cell.

### TECHNICAL FIELD

The application relates to a solar cell, and more particularly to a high efficiency solar cell.

### REFERENCE TO RELATED APPLICATION

This application claims the right of priority based on TW application Ser. No. 098133677, filed “Oct. 2, 2009”, entitled “A HIGH EFFICIENCY SOLAR CELL” and the contents of which are incorporated herein by reference in its entirety.

### DESCRIPTION OF BACKGROUND ART

There are many types of photoelectronic elements such as light-emitting diodes (LEDs), solar cells, or photo diodes. Because of the shortage of the petroleum energy resource and the promotion of the environment protection, people continuously and actively study the art related to the replaceable energy resource and the regenerative energy resource. The solar cell is an attractive candidate among those replaceable energy resources and the regenerative energy resources because the solar cell can directly convert solar energy into electricity. In addition, there are no injurious substances like carbon oxide or nitride generated during the process of generating electricity so there is no pollution to the environment. The InGaP/GaAs/Ge triple-junctions solar cell is the most potential among the solar cells. The converting efficiency of the InGaP/GaAs/Ge triple-junctions solar cell has not, however, reached the optimum yet. One of the reasons is that the band gaps of the InGaP, GaAs, and Ge can not match with each other. The band gap of the InGaP top cell is about 1.85 eV and the current generated therefrom is about 18 mA/cm²˜20 mA/cm². The band gap of the GaAs middle cell is about 1.405 eV and the current generated therefrom is about 14 mA/cm²˜16 mA/cm². The band gap of the Ge bottom cell, however, is about 0.67 eV and the current generated therefrom is larger, for instance, about 26 mA/cm²˜30 mA/cm². The difference of the current generated from Ge bottom cell, GaAs middle cell, and InGaP top cell is larger so that the loss of the current and voltage of the triple-junctions solar cell is happened and the converting efficiency thereof is reduced.

Each of the foregoing photoelectronic elements such as solar cells can include a substrate and a contact, and the substrate can further be connected to a submount via solders or adhesive elements to form a light-emitting device or a light-absorbing device. Moreover, the submount includes at least a circuit to be electrically connected to the contact of the photoelectronic element via a conductive structure, such as wire lines.

### SUMMARY OF THE DISCLOSURE

A solar cell includes a substrate; a buffer layer formed on the substrate; a SiₓGe₍₁₋ₓ₎ bottom cell formed on the buffer layer, wherein x is a real number, and 0.005<x<0.065; a first tunneling layer formed on the SiₓGe₍₁₋ₓ₎ bottom cell; a GaN_{y}As_{(1-y)} middle cell formed on the first tunneling layer, wherein y is a real number, and 0.002<y<0.02; a second tunneling layer formed on the GaN_{y}As_{(1-y)} middle cell; a Ga_{z}In_{(1-z)}P top cell formed on the second tunneling layer, wherein z is a real number, and 0.52<z<0.57; and a contact layer formed on the Ga_{z}In_{(1-z)}P top cell.

### BRIEF DESCRIPTION OF THE DRAWINGS

FIG. 1 illustrates a cross-sectional view of an embodiment of the present application.

FIG. 2 illustrates a diagram of the lattice constants and the band gap.

FIG. 3 illustrates a diagram of the efficiency of the embodiment of the present application.

### DETAILED DESCRIPTION OF PREFERRED EMBODIMENTS

The embodiments of present application will be described in detail and sketched in figures. The same or similar parts will be shown with the same numbers in every figure and the specification.

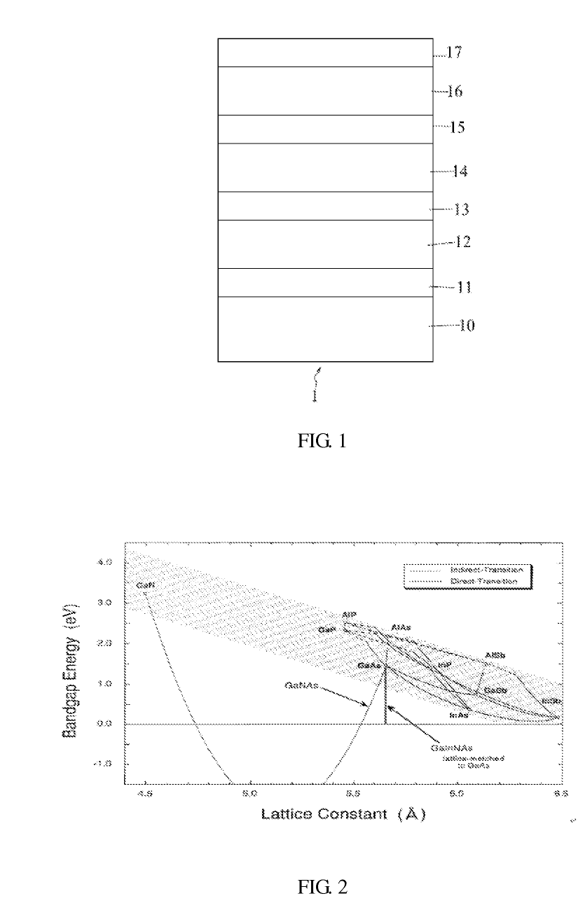

As FIG. 1 shows, a solar cell 1 includes a substrate 10; a buffer layer 11 located on the substrate 10; a SiₓGe₍₁₋ₓ₎ bottom cell 12 located on the buffer layer 11, wherein x is a real number, and 0<x<1, preferably 0.005<x<0.065; a first tunneling layer 13 located on the SiₓGe₍₁₋ₓ₎ bottom cell 12; a GaN_{y}As_{(1-y)} middle cell 14 located on the first tunneling layer 13, wherein y is a real number, and 0<y<1, preferably 0.002<y<0.02; a second tunneling layer 15 located on the GaN_{y}As_{(1-y)} middle cell 14; a Ga_{z}In_{(1-z)}P top cell 16 located on the second tunneling layer 15, wherein z is a real number, and 0<z<1, preferably 0.52<z<0.57; and a contact layer 17 located on the Ga_{z}In_{(1-z)}P top cell 16.

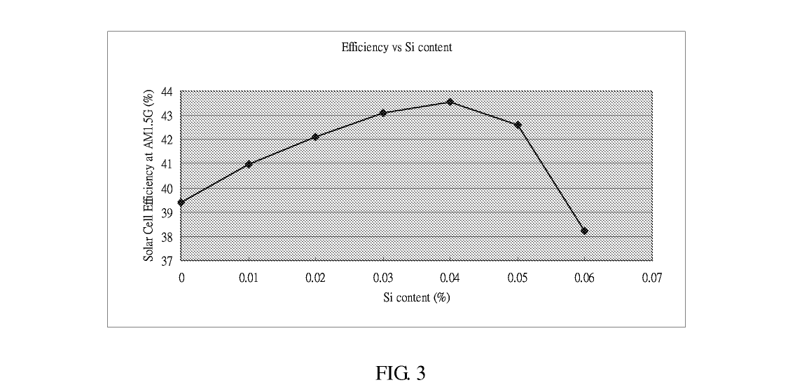

The band gap of the Ge bottom cell is conventionally smaller so the current generated therefrom is larger and the current of the Ge bottom cell does not match with that of the middle cell and the top cell. The SiₓGe₍₁₋ₓ₎ bottom cell 12 of this embodiment is employed to increase the band gap of the bottom cell so the current of the bottom cell can match with that of the middle cell and the top cell. The formula of the band gap of the SiₓGe₍₁₋ₓ₎ is provided in Douglas J Paul, Advanced Materials, 11(3), p. 191-204 (1999). The formula of lattice constant of SiₓGe₍₁₋ₓ₎ is provided in F. M. Bulfer et al. Journal Applied Physics, Vol. 84, No. 10, p. 5597 (1998). The two papers are incorporated herein by reference in their entirety. According to E_{g}(x)=0.74+1.27 x, a₀(x)=5.6500996−0.2239666x+0.01967 x², wherein E_{g} is the band gap and x is a real number and represents the content of Si in SiₓGe₍₁₋ₓ₎, for instance, the band gap of Si_{0.04}Ge_{0.96} is 0.791 eV and the lattice constant thereof is 5.641 Å when x is 0.04. The lattice constant of the GaN_{0.0092}As_{0.9908} middle cell is 5.641 Å and matches with that of the Si_{0.04}Ge_{0.96} bottom cell according to FIG. 2. In addition, the formula of the band gap of the GaN_{y}As_{(1-y)} is provided in Shih-Chang Lee, “Epitaxial Growth of GaNAs Material and Study of Wet Oxidation of AlAs”, NCTU, 2001. This paper is incorporated herein by reference in its entirety. According to E_{g} (y)=1.424−15.7y+216y², wherein y is a real number and represents the content of N in GaN_{y}As_{(1-y)}, the band gap of GaN_{0.0092}As_{0.9908} middle cell is 1.298 eV. The lattice constant of the Ga_{0.544}In₄₅₆P matches with that of the Si_{0.04}Ge_{0.96} bottom cell and GaN_{0.0092}As_{0.9908} middle cell according to FIG. 2, similarly. The formula of the band gap of the Ga_{z}In_{(1-z)}P is provided in Prasanta Kumar Basu, “Theory of optical processes in semiconductors: bulk and microstructures”, tbl. 4.2, p. 67. This paper is incorporated herein by reference in its entirety. According to E_{g} (z)=1.35+0.643z+0.786z², wherein z is a real number and represents the content of Ga in Ga_{z}In_{(1-z)}P, the band gap of Ga_{0.544}In₄₅₆P top cell is 1.847 eV. The difference of the band gap of each cell is less and the lattice constant thereof matches more in this embodiment. The currents generated from Si_{0.04}Ge_{0.96} bottom cell to Ga_{0.544}In₄₅₆P top cell are 19.21 mA/cm², 17.92 mA/cm², and 17.92 mA/cm² respectively. Therefore, the currents generated therefrom are more matching and the converting efficiency is increased, as FIG. 3 shows.

As FIG. 3 shows, the converting efficiency of the solar cell can be increased when the content of Si is increased in SiₓGe₍₁₋ₓ₎ bottom cell 12. The converting efficiency is the largest and about 43.54% when the content of Si is 0.04 in SiₓGe₍₁₋ₓ₎ bottom cell 12.

The substrate 10 supports the cell structure thereon and can be electrically or thermally conductive. The material of the substrate 10 can be electrical-conductive materials such as Si, Ge, GaAs, InP, SiGe, or SiC. The buffer layer 11 can reduce the difference of the lattice constants between the SiₓGe₍₁₋ₓ₎ bottom cell 12 and the substrate 10 to reduce the stress or strain. The material of the buffer layer 11 can be SiᵤGe₍₁₋ᵤ₎ or InᵤGa₍₁₋ᵤ₎P. The first tunneling layer 13 and the second tunneling layer 15 connect the SiₓGe₍₁₋ₓ₎ bottom cell 12, the GaN_{y}As_{(1-y)} middle cell 14, and Ga_{z}In_{(1-z)}P top cell 16 and can be electrically conductive. The material of the tunneling layers can be GaAsᵤN₍₁₋ᵤ₎, InᵤGa₍₁₋ᵤ₎P, or AlᵤGa₍₁₋ᵤ₎As. The contact layer 17 can reduce the series resistance between the solar cell and the metal electrode and the material thereof can be InᵤGa₍₁₋ᵤ₎As or InᵤGa₍₁₋ᵤ₎P. The aforementioned u is a real number and represents the content of In in InᵤGa₍₁₋ᵤ₎As or InᵤGa₍₁₋ᵤ₎P, 0≦u≦1.

Although the present application has been explained above, it is not the limitation of the range, the sequence in practice, the material in practice, or the method in practice. Any modification or decoration for present application is not detached from the spirit and the range of such.

What is claimed is:

1. A multi-junction solar cell, comprising:
a SiₓGe₁₋ₓ₎ bottom cell, wherein x is a real number, and 0<x<1;
a GaN_{y}As_{(1-y)} middle cell formed on the SiₓGe₍₁₋ₓ₎ bottom cell, wherein y is a real number, and 0<y<1; and
a Ga_{z}In_{(1-z)}P top cell formed on the GaN_{y}As_{(1-y)} middle cell, wherein z is a real number, and 0<z<1.

2. The multi junction solar cell of claim 1, wherein 0.005<x<0.065.

3. The multi-junction solar cell of claim 1, wherein 0.002<y<0.02.

4. The multi-junction solar cell of claim 1, wherein 0.52<z<0.57.

5. The multi-junction solar cell of claim 1, further comprising a substrate located under the SiₓGe₍₁₋ₓ₎ bottom cell.

6. The multi junction solar cell of claim 5, wherein the substrate comprises a material selected from a group consisting of Si, Ge, GaAs, InP, SiGe, and SiC.

7. The multi-junction solar cell of claim 1, further comprising a first tunneling layer located between the SiₓGe₍₁₋ₓ₎ bottom cell and the GaN_{y}As_{(1-y)} middle cell.

8. The multi junction solar cell of claim 1, further comprising a second tunneling layer located between the GaN_{y}As_{(1-y)} middle cell and the Ga_{z}In_{(1-z)}P top cell.

9. The multi-junction solar cell of claim 1, wherein x=0.04.

10. A multi-junction solar cell, comprising:
a SiₓGe₍₁₋ₓ₎ bottom cell, wherein x is a real number, and 0<x<1; and
a GaN_{y}As_{(1-y)} middle cell formed on the SiₓGe₍₁₋ₓ₎ bottom cell, wherein y is a real number, and 0<y<1.

11. The multi-junction solar cell of claim 10, wherein 0.005<x<0.065.

12. The multi-junction solar cell of claim 10, wherein x=0.04.

13. The multi junction solar cell of claim 10, wherein 0.002<y<0.02.

14. The multi-junction solar cell of claim 10, further comprising a Ga_{z}In_{(1-z)}P top cell formed on the GaN_{y}As_{(1-y)} middle cell, wherein z is a real number, and 0<z<1.

15. The multi-junction solar cell of claim 14, wherein 0.52<z<0.57.

16. The multi-junction solar cell of claim 14, further comprising a second tunneling layer located between the GaN_{y}As_{(1-y)} middle cell and the Ga_{z}In_{(1-z)}P top cell.

17. The multi junction solar cell of claim 10, further comprising a substrate located under the SiₓGe₍₁₋ₓ₎ bottom cell.

18. The multi-junction solar cell of claim 17, wherein the substrate comprises a material selected from a group consisting of Si, Ge, GaAs, InP, SiGe, and SiC.

19. The multi-junction solar cell of claim 10, further comprising a first tunneling layer located between the SiₓGe₍₁₋ₓ₎ bottom cell and the GaN_{y}As_{(1-y)} middle cell.
